(19) United States
(12) Patent Application Publication
(10) Pub. No.: US 2026/0155199 A1
(43) Pub. Date: Jun. 4, 2026

(54) SEMICONDUCTOR DEVICE

(71) Applicant: Renesas Electronics Corporation, Tokyo (JP)

(72) Inventors: Yohei SAWADA, Tokyo (JP); Masao MORIMOTO, Tokyo (JP); Daiki KITAGATA, Tokyo (JP)

(21) Appl. No.: 19/259,767

(22) Filed: Jul. 3, 2025

Related U.S. Application Data
(60) Provisional application No. 63/689,167, filed on Aug. 30, 2024.
(60) Provisional application No. 63/689,973, filed on Sep. 3, 2024.

(30) Foreign Application Priority Data
Feb. 14, 2025 (JP) 2025-022555

(51) Int. Cl. G11C 29/50; G11C 11/412; G11C 11/419; G11C 29/12; H10B 10/00

(52) U.S. Cl. CPC G11C 29/50012; G11C 11/412; G11C 11/419; G11C 29/1201; H10B 10/12; H10B 10/18; G11C 2029/1204

(57) ABSTRACT

Each latch cell in a latch cell array is made of 12 MOS transistors including a first CMOS switch transferring write data and a second CMOS switch transferring read data. A test for rewriting a storage node on a write bit line side in each latch cell from a first logic level to a second logic level in a state in which the first and second CMOS switches are respectively controlled to be on in overlapping time periods is assumed. In this case, a disturb test circuit precharges a read bit line to the second logic level before the second CMOS switch is controlled to be on.

### CROSS-REFERENCE TO RELATED APPLICATION

The present application claims priority to U.S. Provisional Ser. No. 63/689,167, filed on Aug. 30, 2024, U.S. Provisional Ser. No. 63/689,973, filed Sep. 3, 2024, and the benefit of foreign priority to Japanese Patent Application No. 2025-022555, filed Feb. 14, 2025, the entire contents of each of which are hereby incorporated by reference.

### BACKGROUND

The present invention relates to a semiconductor device, and relates to, for example, a semiconductor device including a memory.

There are disclosed techniques listed below.

[Non-Patent Document 1] M. Sinangil, et al., “A 290 mV Ultra-Low Voltage One-Port SRAM Compiler Design Using a 12T Write Contention and Read Upset Free Bit-Cell in 7 nm FinFET Technology”, VLSI 2018 Non Patent Document 2: H. Fujiwara, et al., “A 5 nm 5.7 GHz@1.0V and 1.3 GHz@0.5V 4 kb Standard-Cell-Based Two-Port Register File with a 16T Bitcell with_No Half-Selection Issue”, ISSCC 2021

The Non Patent Document 1 discloses an SRAM macro including a memory cell made of 12 transistors. The memory cell is made of a write port circuit, a latch circuit, and a read port circuit. The write port circuit is made of a transfer gate made of two transistors. The latch circuit is made of six transistors each including two cross-coupled CMOS inverter circuits. The read port circuit is made of a driver circuit made of four transistors.

The Non Patent Document 2 discloses an SRAM macro including a memory cell made of 16 transistors. The memory cell is made of a write port circuit, a latch circuit, and a read port circuit. The write port circuit is made of a driver circuit made of four transistors. The latch circuit is made of eight transistors each including two cross-coupled CMOS inverter circuits and also corresponding to a bit write mask operation. The read port circuit is made of a driver circuit made of four transistors.

### SUMMARY

In recent years, for example, semiconductor devices that execute various types of artificial intelligence (AI) processing typified by image recognition have been widespread. In such a semiconductor device, for example, various distributed portions in the device are desired to temporarily store processing data. Accordingly, a memory with high speed and certain small capacity is required. As such a memory, a flip-flop, an SRAM (static random access memory), and others have been known.

When the SRAM has, for example, a single port, a memory cell can be made of six transistors. However, in the SRAM, a peripheral circuit including various circuits typified by a decoder, a sense amplifier, a write assist circuit, a read assist circuit, and the like is required. Accordingly, in the SRAM, the smaller the capacity of the SRAM is, the larger an area thereof per bit is. That is, the area efficiency decreases. On the other hand, the flip-flop may include only the decoder as the peripheral circuit. However, the flip-flop is made of, for example, two D-latches each made of about 20 transistors. Accordingly, the flip-flop has the large area thereof per bit, and is applied only to a case with sufficiently small capacity in practice.

A memory that complements a function between the SRAM and the flip-flop is required from the viewpoint of increasing the area efficiency. As a specific example, a memory appropriate to hold about 16 to 64 pieces of 128-bit data is required. One example of such memories is a D-latch macro. The D-latch macro can be made of, for example, a memory cell, in other words, a latch cell made of 16 transistors as disclosed in the Non-Patent Document 2. The D-latch macro can also be made as a two-port memory that can independently execute a read operation and a write operation.

In assumption that, for example, a large number of small-capacity D-latch macros are arranged in the semiconductor device, a further reduction in the area of the D-latch macros is desired. In order to achieve the area reduction, it is beneficial to reduce the number of transistors of the latch cell. However, in this case, particularly when the D-latch macro is made as the two-port memory, an influence of a port-to-port interference may be large, and the stability of the latch cell may decrease. The port-to-port interference is a phenomenon in which, when the read operation and the write operation are simultaneously executed in the same latch cell in the two-port memory, one of the operations interrupts the other operation.

On the other hand, manufacturing of the latch cell may vary. Accordingly, the large influence of the port-to-port interference may cause, for example, an unstable latch cell that may be defective in the market. For example, in a wafer test, it is desired to reproduce the worst state maximizing the influence of the port-to-port interference to detect the unstable latch cell. This manner can remove the semiconductor device having the unstable latch cell at an early stage. Alternatively, if the semiconductor device includes a relief latch cell, the unstable latch cell can be relieved. As a result, a defect yield of the semiconductor devices can be reduced at a stage of a final test after the wafer test or at a stage of the market after shipment.

However, it may be difficult to reproduce the worst state only by a normal external signal to the D-latch macro. Alternatively, in order to reproduce the worst state, it may be necessary to input and output a complicated test pattern using a plurality of cycles. As a result, there is a risk of failure to reduce the defect yield of the semiconductor devices in the market only by a normal wafer test using the normal external signal.

An embodiment described below has been made in view of such circumstances, and other problems and novel characteristics will be apparent from the description of the present specification and the accompanying drawings.

A semiconductor device according to one embodiment includes a pair of write selection lines, a pair of read selection lines, a plurality of pairs of bit write mask selection lines, and a plurality of latch cells connected thereto. The pair of write selection lines are activated in a write operation. The pair of read selection lines are activated in a read operation. The plurality of pairs of bit write mask selection lines are activated in execution of a write operation of a high impedance to any one of the plurality of latch cells. The semiconductor device further includes a plurality of read bit lines transferring read data from the plurality of latch cells, and a plurality of write bit lines transferring write data to the plurality of latch cells. The semiconductor device still further includes a plurality of first test circuits being connected to the plurality of read bit lines. Each of the plurality of latch cells includes first and second storage nodes, first, second, third, fourth, fifth, and sixth nMOS transistors, and first, second, third, fourth, fifth, and sixth pMOS transistors. The first and second storage nodes store complementary data. The first nMOS transistor is connected between the first storage node and a first intermediate node, and has a gate connected to the second storage node. The second nMOS transistor is connected between the second storage node and a low potential-side power supply node, and has a gate connected to the first storage node. The third nMOS transistor is connected between the first intermediate node and a low potential-side power supply node, and is controlled by the pair of write selection lines. The sixth nMOS transistor is connected between the first intermediate node and the low potential-side power supply node, and is controlled by the pair of bit write mask selection lines. The first, second, third, and sixth pMOS transistors are provided between themselves and a high potential-side power supply node, as similar to the first, second, third, and sixth nMOS transistors. The fourth nMOS transistor and the fourth pMOS transistor configure a first CMOS switch controlled by the pair of write selection lines, and connect a predetermined write bit line to the first storage node when being controlled to be on. The fifth nMOS transistor and the fifth pMOS transistor configure a second CMOS switch controlled by the pair of read selection lines, and connect the second storage node to a predetermined read bit line when being controlled to be on. A test for rewriting the first storage node from a first logic level to a second logic level in a state in which the first and second CMOS switches are respectively controlled to be on in overlapping time periods is referred to as a disturb write test. The plurality of first test circuits precharge the plurality of read bit lines to the second logic level before the second CMOS switch is controlled to be on in execution of the disturb write test.

According to the one embodiment, in the semiconductor device including the small-capacity memory, the area can be reduced, and the defect yield in the market can be reduced.

### BRIEF DESCRIPTIONS OF THE DRAWINGS

FIG. 1 is a schematic view illustrating a configuration example of a semiconductor device according to one embodiment.

FIG. 2 is a schematic view illustrating a configuration example of a principal part of a peripheral circuit in a memory illustrated in FIG. 1.

FIG. 3 is a circuit diagram illustrating a configuration example of a latch cell illustrated in FIG. 1.

FIG. 4A is a timing chart illustrating an example of a write operation executed by the latch cell illustrated in FIG. 3.

FIG. 4B is a schematic view for supplimentarily describing the operation illustrated in FIG. 4A.

FIG. 5A is a timing chart illustrating an example of a read operation executed by the latch cell illustrated in FIG. 3.

FIG. 5B is a schematic view for supplimentarily describing the operation illustrated in FIG. 5A.

FIG. 6A is a timing chart illustrating an example of a bit write mask operation executed by the latch cell illustrated in FIG. 3.

FIG. 6B is a schematic view for supplimentarily describing the operation illustrated in FIG. 6A.

FIG. 7 is a schematic view illustrating an example of a worst state caused by a port-to-port interference in the write operation in the semiconductor device illustrated in FIGS. 1 and 3.

FIG. 8 is a schematic view illustrating an example of a worst state caused by a port-to-port interference in the read operation in the semiconductor device illustrated in FIGS. 1 and 3.

FIG. 9 is a circuit diagram illustrating a more detailed configuration example of a data input/output circuit illustrated in FIG. 2.

FIG. 10 is a timing chart illustrating an operation example of a disturb write test using a disturb test circuit illustrated in FIG. 9.

FIG. 11 is a schematic view for supplementarily describing a precharge operation executed by the disturb test circuit in FIG. 10.

FIG. 12 is a timing chart illustrating an operation example of a disturb read test using two disturb test circuits illustrated in FIG. 9.

FIG. 13 is a schematic view for supplementarily describing a precharge operation executed by the two disturb test circuits in FIG. 12.

FIG. 14 is a flowchart illustrating an example of a method of manufacturing the semiconductor device according to one embodiment.

FIG. 15 is a flowchart illustrating an example of a disturb write test illustrated in FIG. 14.

FIG. 16 is a flowchart illustrating an example of a disturb read test illustrated in FIG. 14.

FIG. 17 is a circuit diagram illustrating a configuration example of a latch cell as a comparative example.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

In the embodiment, a MOSFET (MOS field effect transistor) is referred to as a MOS transistor. A p-channel MOSFET and an n-channel MOSFET are respectively referred to as a pMOS transistor and an nMOS transistor. In the embodiment, in order to simplify description, the description is made using a MOS transistor using an oxide film as a gate insulating film. However, the gate insulating film is not necessarily limited to the oxide film.

Hereinafter, embodiments of the present invention will be described in detail with reference to the accompanying drawings. Note that the same components are denoted by the same reference symbols throughout all the drawings for describing the embodiments, and the repetitive description thereof is omitted.

### OUTLINE OF SEMICONDUCTOR DEVICE

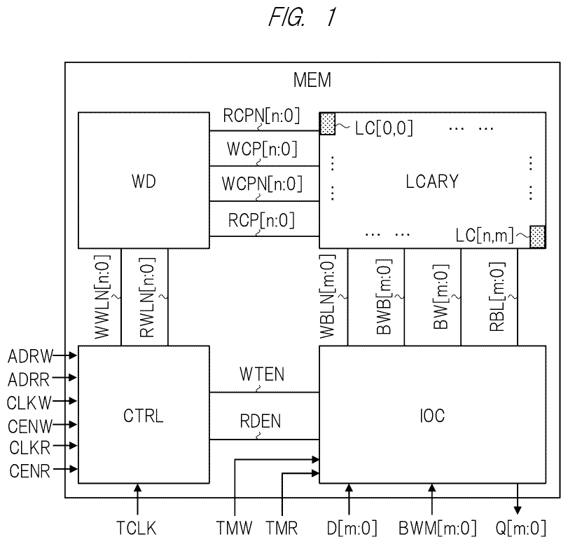

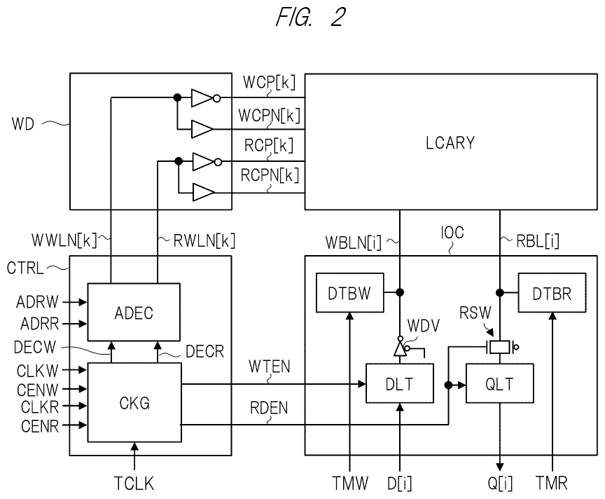

FIG. 1 is a schematic view illustrating a configuration example of a semiconductor device according to one embodiment. FIG. 2 is a schematic view illustrating a configuration example of a principal part of a peripheral circuit in a memory MEM illustrated in FIG. 1. The semiconductor device according to the one embodiment includes at least the memory MEM as illustrated in FIG. 1. The memory MEM is, for example, a D-latch macro made of a hard macro. The semiconductor device includes, for example, various types of logic circuits that execute various types of AI processing. In this case, the semiconductor device may include the memories MEM as illustrated in FIG. 1 to be distributed in portions of the device in order to temporarily store processing data of the various types of logic circuits.

The memory MEM illustrated in FIG. 1 is a two-port memory that can independently execute the read operation and the write operation. The memory MEM includes a latch cell array LCARY, a memory control circuit CTRL, a word driver circuit WD, and a data input/output circuit IOC. The memory control circuit CTRL, the word driver circuit WD, and the data input/output circuit IOC are respectively peripheral circuits of the latch cell array LCARY. The latch cell array LCARY includes “N (=n+1)*M(=m+1)” latch cells LC[0, 0] to LC[n, m] arranged in a matrix pattern. In the specification, the plurality of latch cells LC[0, 0] to LC[n, m] are collectively referred to as a latch cell LC.

The memory control circuit CTRL controls the entire memory MEM. The memory control circuit CTRL mainly includes a clock generation circuit CKG and an address decoder ADEC, as illustrated in FIG. 2. The clock generation circuit CKG receives various types of input signals as its input from outside of the memory MEM. The various types of input signals include a use-in-writing clock signal CLKW and a use-in-writing chip enable signal CENW and a use-in-reading clock signal CLKR and a use-in-reading chip enable signal CENR.

The clock generation circuit CKG outputs a write decode instruction signal DECW to the address decoder ADEC, based on the use-in-writing clock signal CLKW and the use-in-writing chip enable signal CENW. In parallel with this, the clock generation circuit CKG outputs a write enable signal WTEN to the data input/output circuit IOC. The clock generation circuit CKG outputs a read decode instruction signal DECR to the address decoder ADEC, based on the use-in-reading clock signal CLKR and the use-in-reading chip enable signal CENR. In parallel with this, the clock generation circuit CKG outputs a read enable signal RDEN to the data input/output circuit IOC.

The address decoder ADEC receives a use-in-writing address signal ADRW as its input from outside of the memory MEM. The address decoder ADEC activates a single write word line WWLN[k] based on the use-in-writing address signal ADRW in response to the write decode instruction signal DECW. This write word line WWLN[k] is any one of N write word lines WWLN[n:0] illustrated in FIG. 1.

Similarly, the address decoder ADEC receives a use-in-reading address signal ADRR as its input from outside of the memory MEM. The address decoder ADEC activates a single read word line RWLN[k] based on the use-in-reading address signal ADRR in response to the read decode instruction signal DECR. This read word line RWLN[k] is any one of N read word lines RWLN[n:0] illustrated in FIG. 1.

The two-port memory may receive the use-in-writing address signal ADRW and the use-in-reading address signal ADRR, which are both defined to the same value, as its input in overlapping time periods. In this case, the write word line WWLN[k] and the read word line RWLN[k], which are directed toward the same latch cell LC, may be respectively activated in the overlapping time periods.

Although described in detail later, the clock generation circuit CKG further receives a use-in-testing clock signal TCLK as its input. The clock generation circuit CKG activates the write word line WWLN[k] and the read word line RWLN[k], which are directed toward the same latch cell LC, respectively, in the overlapping time periods in response to the use-in-testing clock signal TCLK. For example, the clock generation circuit CKG simultaneously activates the write word line WWLN[k] and the read word line RWLN[k]. The write word line WWLN[k] and the read word line RWLN[k] to be activated are defined by, for example, the two address signals ADRW and ADRR that both have the same value.

The word driver circuit WD drives a pair, more specifically N pairs of read selection lines RCP[n:0] and RCPN[n:0] as complementary signal lines, as illustrated in FIG. 1. The N read selection lines RCP[n:0] are respectively non-inverted-side signal lines. In the specification, the N read selection lines RCP[n:0] are collectively referred to as a non-inverted-side read selection line RCP or simply a read selection line RCP. On the other hand, the remaining N read selection lines RCPN[n:0] are respectively inverted-side signal lines. In the specification, the N read selection lines RCPN[n:0] are collectively referred to as an inverted-side read selection line RCPN or simply a read selection line RCPN.

The word driver circuit WD drives a pair, more specifically N pairs of write selection lines WCP[n:0] and WCPN[n:0] as complementary signal lines. The N write selection lines WCP[n:0] are respectively non-inverted-side signal lines. In the specification, the N write selection lines WCP[n:0] are collectively referred to as a non-inverted-side write selection line WCP or simply a write selection line WCP. On the other hand, the remaining N write selection lines WCPN[n:0] are respectively inverted-side signal lines. In the specification, the N write selection lines WCPN[n:0] are collectively referred to as an inverted-side write selection line WCPN or simply a write selection line WCPN.

As illustrated in FIG. 2, the word driver circuit WD receives a signal on each read word line RWLN[k] as its input, and drives each inverted-side read selection line RCPN[k]. The word driver circuit WD inverts the signal on each read word line RWLN[k], to drive each non-inverted-side read selection line RCP[k]. Similarly, the word driver circuit WD receives a signal on each write word line WWLN[k] as its input, and drives each inverted-side write selection line WCPN[k]. The word driver circuit WD inverts the signal on each write word line WWLN[k], to drive each non-inverted-side write selection line WCP[k].

The data input/output circuit IOC controls input/output of data to/from outside of the memory MEM. Specifically, the data input/output circuit IOC mainly includes a write latch circuit DLT and a write driver WDV as a write circuit. The data input/output circuit IOC mainly includes a read switch RSW and a read latch circuit QLT as a read circuit.

Although described in detail later, the data input/output circuit IOC further includes two disturb test circuits DTBR and DTBW. The two disturb test circuits DTBR and DTBW are used in execution of a disturb test for detecting the unstable latch cell LC that is easily influenced by the port-to-port interference. The disturb test circuit DTBR is controlled to be enabled/disabled, based on a test mode signal TMR from outside. Similarly, the disturb test circuit DTBW is controlled to be enabled/disabled, based on a test mode signal TMW from outside.

In the write operation, the data input/output circuit IOC receives M-bit external input data D[m:0] as its input from outside of the memory MEM, as illustrated in FIG. 1. The write latch circuit DLT latches the M-bit external input data D[m:0] as write data in response to the write enable signal WTEN. The write driver WDV transfers the latched M-bit write data to the latch cell array LCARY through M inverted-side write bit lines WBLN[m:0].

The M-bit write data transferred from the write driver WDV is written into the M latch cells LC connected to the activated write selection line WCP. In the specification, the M inverted-side write bit lines WBLN[m:0] are collectively referred to as an inverted-side write bit line WBLN or simply a write bit line WBLN.

On the other hand, in the read operation, the data input/output circuit IOC receives respective read data as its input from the M latch cells LC through M non-inverted-side read bit lines RBL[m:0]. The M latch cells LC are each a cell connected to the activated read selection line RCP. In the specification, the M non-inverted-side read bit lines RBL[n:0] are collectively referred to as a non-inverted-side read bit line RBL or simply a read bit lines RBL.

The read latch circuit QLT receives and latches the respective read data as its input from the M latch cells LC through the read switch RSW in response to the read enable signal RDEN. That is, as different from a normal SRAM, the read latch circuit QLT receives and latches the read data as its input without passing through a sense amplifier. Then, the read latch circuit QLT outputs the latched M-bit read data as M-bit external output data Q[m:0] to outside.

The data input/output circuit IOC further receives an M-bit bit write mask signal BWM[m:0] as its input from outside of the memory MEM, as illustrated in FIG. 1. The bit write mask signal BWM[m:0] is used in the write operation when some of bits of the M-bit external input data D[m:0] are masked. This eliminates, for example, need for a read-modify-write operation.

In the bit write mask operation, the write driver WDV illustrated in FIG. 2 outputs a high impedance to the write bit line WBLN[k] of the bit to be masked. This allows the latch cell LC connected to this write bit line WBLN[k] to maintain the currently stored data, regardless of the write operation.

In the bit write mask operation, the data input/output circuit IOC drives a pair (specifically M pairs) of bit write mask selection lines BW[m:0] and BWB[m:0] as complementary signal lines. Although described in detail later, the driving of the selection lines allows the latch cell LC to maintain the currently stored data. In the specification, the M inverted-side bit write mask selection lines BWB[m:0] are collectively referred to as an inverted-side bit write mask selection line BWB or simply a bit write mask selection line BWB. Similarly, the M non-inverted-side bit write mask selection lines BW[m:0] are collectively referred to as a non-inverted-side bit write mask selection line BW or simply a bit write mask selection line BW.

In FIG. 1, a value of M (=m+1) representing a bit width is, for example, 128, 256, 512, 1024 or the like. A value of N (=n+1) representing the number of word lines is, for example, 16, 32, 64 or the like. Generally, within such a range of the memory capacity, the D-latch macro can be more advantageous than the flip-flop and the SRAM from the viewpoint of the area efficiency. The D-latch macro can also be said to be a macro in which an area ratio between a data storage region and a peripheral circuit region is intermediate between those of the flip-flop and the SRAM.

For example, in the SRAM, the data input/output circuit IOC can include sense amplifiers, various types of assist circuits or the like, the number of which corresponds to the bit width. Accordingly, the larger the bit width is, the higher the area ratio of the data input/output circuit IOC is. On the other hand, the D-latch macro does not need the sense amplifiers, the various types of assist circuits and the like. Accordingly, the area ratio of the data input/output circuit IOC is not so high even if the bit width is large. As a result, in the D-latch macro, the area efficiency can be increased even if the bit width is large.

### CONFIGURATION OF LATCH CELL (EMBODIMENT)

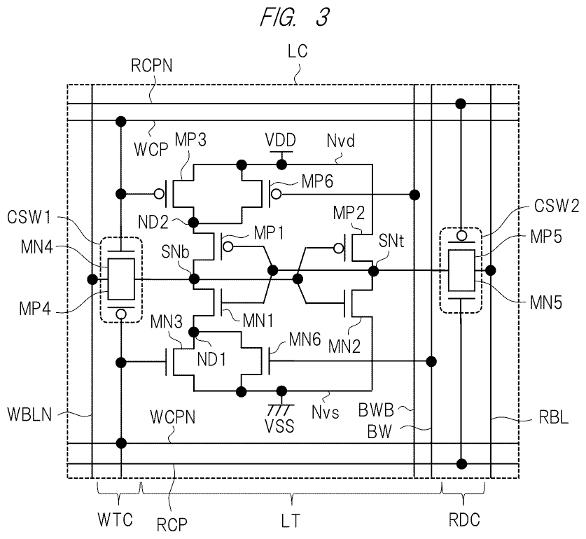

FIG. 3 is a circuit diagram illustrating a configuration example of the latch cell LC illustrated in FIG. 1. The latch cell LC illustrated in FIG. 3 includes a write port circuit WTC, a latch circuit LT, and a read port circuit RDC. The latch cell LC includes an inverted-side storage node (first storage node) SNb and a non-inverted-side storage node (second storage node) SNt that respectively store complementary data.

The latch circuit LT includes four nMOS transistors MN1 to MN3 and MN6 and four pMOS transistors MP1 to MP3 and MP6. The pMOS transistor (first pMOS transistor) MP1 and the nMOS transistor (first nMOS transistor) MN1 configure a first inverter circuit. The first inverter circuit executes a signal inversion operation using the non-inverted-side storage node SNt/inverted-side storage node SNb as input/output.

The pMOS transistor (second pMOS transistor) MP2 and the nMOS transistor (second nMOS transistor) MN2 configure a second inverter circuit. The second inverter circuit executes a signal inversion operation using the inverted-side storage node SNb/non-inverted-side storage node SNt as input/output.

The pMOS transistor (third pMOS transistor) MP3 is connected between the first inverter circuit and a high potential-side power supply node Nvd. The nMOS transistor (third nMOS transistor) MN3 is connected between the first inverter circuit and a low potential-side power supply node Nvs. A high potential-side power supply voltage VDD is supplied to the high potential-side power supply node Nvd. A low potential-side power supply voltage VSS is supplied to the low potential-side power supply node Nvs.

The pMOS transistor (sixth pMOS transistor) MP6 is connected in parallel with the pMOS transistor MP3. The nMOS transistor (sixth nMOS transistor) MN6 is connected in parallel with the nMOS transistor MN3. Although described in detail later, the pMOS transistor MP6 and the nMOS transistor MN6 are provided to achieve the bit write mask function. Therefore, when the bit write mask function is unnecessary, the pMOS transistor MP6 and the nMOS transistor MN6 may be omitted.

The write port circuit WTC is made of a pMOS transistor (fourth MOS transistor) MP4 and an nMOS transistor (fourth nMOS transistor) MN4. The pMOS transistor MP4 and the nMOS transistor MN4 configure a CMOS (complementary MOS) switch (first CMOS switch) CSW1, in other words, a transfer gate. The CMOS switch CSW1 transfers the write data to the inverted-side storage node SNb when being controlled to be on.

On the other hand, the read port circuit RDC is made of a pMOS transistor (fifth MOS transistor) MP5 and an nMOS transistor (fifth nMOS transistor) MN5. The pMOS transistor MP5 and the nMOS transistor MN5 configure a CMOS switch (second CMOS switch) CSW2, in other words, a transfer gate. The CMOS switch CSW2 transfers the read data from the non-inverted-side storage node SNt when being controlled to be on.

The latch cell LC illustrated in FIG. 3 is more specifically connected to the eight signal lines (WCP, WCPN, RCP, RCPN, BW, BWB, WBLN, and RBL) as described in FIGS. 1 and 2. A pair of the write selection lines WCP and WCPN are activated in the write operation. A pair of the read selection lines RCP and RCPN are activated in the read operation. The read bit line RBL transfers the read data from the latch cell LC. The write bit line WBLN transfers the write data to the latch cell LC.

A pair of the bit write mask selection lines BW and BWB are activated in the execution of the bit write mask operation. That is, the pair of the bit write mask selection lines BW and BWB are activated in execution of a write operation of a high impedance to any one of the plurality of latch cells LCs. In other words, these signal lines are activated to maintain the data stored in any one of the plurality of latch cells, regardless of the write operation.

The nMOS transistor (first nMOS transistor) MN1 is connected between the inverted-side storage node SNb and an intermediate node (first intermediate node) ND1. The nMOS transistor MN1 has a gate connected to the non-inverted-side storage node SNt. The nMOS transistor (second nMOS transistor) MN2 is connected between the non-inverted-side storage node SNt and the low potential-side power supply node Nvs. The nMOS transistor MN2 has a gate connected to the inverted-side storage node SNb. The nMOS transistor (third nMOS transistor) MN3 is connected between the intermediate node ND1 and the low potential-side power supply node Nvs. The nMOS transistor MN3 has a gate connected to the inverted-side write selection line WCPN.

The pMOS transistor (first pMOS transistor) MP1 is connected between the inverted-side storage node SNb and an intermediate node (second intermediate node) ND2. The pMOS transistor MP1 has a gate connected to the non-inverted-side storage node SNt. The pMOS transistor (second pMOS transistor) MP2 is connected between the non-inverted-side storage node SNt and the high potential-side power supply node Nvd. The pMOS transistor MP2 has a gate connected to the inverted-side storage node SNb. The pMOS transistor (third pMOS transistor) MP3 is connected between the intermediate node ND2 and the high potential-side power supply node Nvd. The pMOS transistor MP3 has a gate connected to the non-inverted-side write selection line WCP.

The nMOS transistor (fourth nMOS transistor) MN4 and the pMOS transistor (fourth pMOS transistor) MP4 are connected in parallel between the write bit line WBLN and the inverted-side storage node SNb. The nMOS transistor MN4 has a gate connected to the non-inverted-side write selection line WCP. The pMOS transistor MP4 has a gate connected to the inverted-side write selection line WCPN. This causes the CMOS switch CSW1 to be controlled by the pair of the write selection lines WCP and WCPN.

The nMOS transistor (fifth nMOS transistor) MN5 and the pMOS transistor (fifth pMOS transistor) MP5 are connected in parallel between the read bit line RBL and the non-inverted-side storage node SNt. The nMOS transistor MN5 has a gate connected to the non-inverted-side read selection line RCP. The pMOS transistor MP5 has a gate connected to the inverted-side read selection line RCPN. This causes the CMOS switch CSW2 to be controlled by the pair of the read selection lines RCP and RCPN.

The nMOS transistor (sixth nMOS transistor) MN6 is connected between the intermediate node ND1 and the low potential-side power supply node Nvs. The nMOS transistor MN6 has a gate connected to the non-inverted-side bit write mask selection line BW. The pMOS transistor (sixth pMOS transistor) MP6 is connected between the intermediate node ND2 and the high potential-side power supply node Nvd. The pMOS transistor MP6 has a gate connected to the inverted-side bit write mask selection line BWB. This causes the nMOS transistor MN6 and the pMOS transistor MP6 to be controlled by the pair of bit write mask selection lines BW and BWB.

### OPERATION OF LATCH CELL

### Write Operation

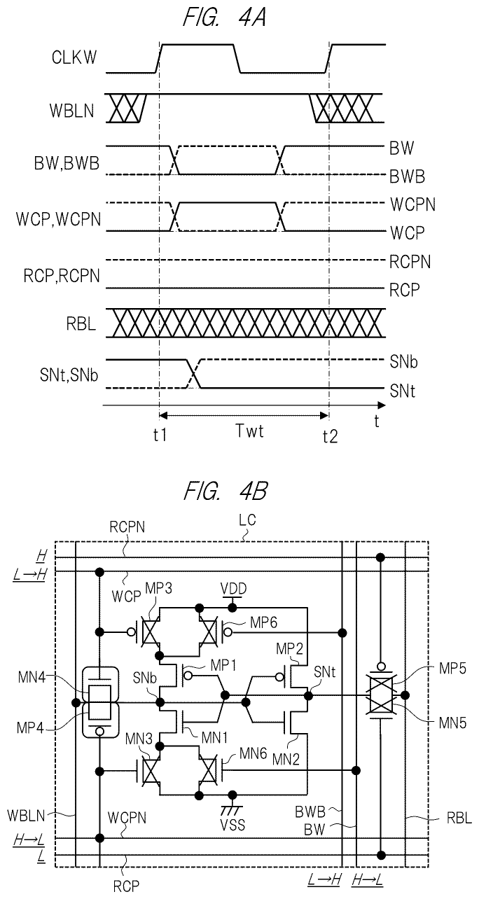

FIG. 4A is a timing chart illustrating an example of the write operation executed by the latch cell LC illustrated in FIG. 3. FIG. 4B is a schematic view for supplimentarily describing the operation illustrated in FIG. 4A. FIG. 4B illustrates a state of each signal line in the latch cell LC and an on/off state of each transistor in the writing period. In FIG. 4A, a period from a time t1 to a time t2, which is one period of the use-in-writing clock signal CLKW, is a writing period Twt.

In the writing period Twt, the read selection line RCP is in the inactive state, that is, with the “L” level in this case. Accordingly, the pMOS transistor MP5 and the nMOS transistor MN5 are each in an off state. The read bit line RBL is maintained with the H level or the L level based on previous read data.

On the other hand, the write selection line WCP shifts from the inactive state to the active state, that is, from the L level to the H level in this case. Correspondingly, the pMOS transistor MP4 and the nMOS transistor MN4 are each switched from the off state to the on state. The pMOS transistor MP3 and the nMOS transistor MN3 are each switched from the on state to the off state. Note that the bit write mask operation is not executed in this case. Accordingly, the bit write mask selection line BW shifts from the active state to the inactive state, that is, from the H level to the L level in this case. Correspondingly, the pMOS transistor MP6 and the nMOS transistor MN6 are each switched from the on state to the off state.

In such a state, it is assumed that, for example, the inverted-side storage node SNb is rewritten from the L level to the H level. The write bit line, specifically the inverted-side write bit line WBLN is with the H level at the time t1. The pMOS transistor MP4 and the nMOS transistor MN4 each in the on state transfer the H level to the storage node SNb with the L level.

In this case, the write bit line WBLN is driven by the write driver WDV illustrated in FIG. 2. On the other hand, the supply of the power supply voltage VSS to the nMOS transistor MN1 is interrupted. Therefore, the inverted-side storage node SNb can be rewritten to the H level. Further, the nMOS transistor MN2 can rewrite the non-inverted-side storage node SNt from the H level to the L level when receiving the H level as its input.

Then, the write selection line WCP shifts from the active state to the inactive state. The bit write mask selection line BW shifts from the inactive state to the active state. Correspondingly, the pMOS transistor MP4 and the nMOS transistor MN4 are each switched from the on state to the off state. The two pMOS transistors MP3 and MP6 and the two nMOS transistors MN3 and MN6 are each switched from the off state to the on state. This results in completion of the write operation.

### READ OPERATION

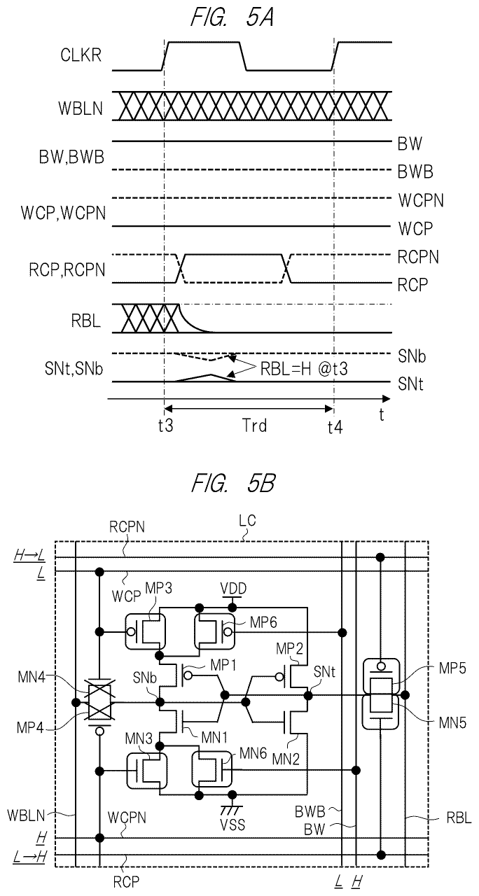

FIG. 5A is a timing chart illustrating an example of the read operation executed by the latch cell LC illustrated in FIG. 3. FIG. 5B is a schematic view for supplimentarily describing the operation illustrated in FIG. 5A. FIG. 5B illustrates a state of each signal line in the latch cell LC and an on/off state of each transistor in the reading period. In FIG. 5A, a period from a time t3 to a time t4, which is one period of the use-in-reading clock signal CLKR, is a reading period Trd.

In the reading period Trd, the write selection line WCP is in the inactive state, that is, with the L level in this case. Accordingly, the pMOS transistor MP4 and the nMOS transistor MN4 are each in the off state. The pMOS transistor MP3 and the nMOS transistor MN3 are each in the on state. The bit write mask selection line BW is in the active state, that is, with the H level in this case. Accordingly, the pMOS transistor MP6 and the nMOS transistor MN6 are each in the on state. On the other hand, the read selection line RCP shifts from the inactive state to the active state, that is, from the L level to the H level in this case. Correspondingly, the pMOS transistor MP5 and the nMOS transistor MN5 are each switched from the off state to the on state.

In such a state, it is assumed that, for example, the non-inverted-side storage node SNt that stores the L level is read out. The read bit line RBL is with the H level or the L level at the time t3. The pMOS transistor MP5 and the nMOS transistor MN5 each in the on state connect the non-inverted-side storage node SNt to the read bit line RBL that is maintained with the H level or the L level. In this case, when the read bit line RBL is previously maintained with the H level, a voltage level of the non-inverted-side storage node SNt may temporarily rise. Correspondingly, a voltage level of the inverted-side storage node SNb may also temporarily slightly drop from the H level.

Then, the read selection line RCP shifts from the active state to the inactive state at a predetermined time at which the read data on the read bit line RBL, that is, the L level in this case is determined. Correspondingly, the pMOS transistor MP5 and the nMOS transistor MN5 are each switched from the on state to the off state. This results in completion of the read operation.

### BIT WRITE MASK OPERATION

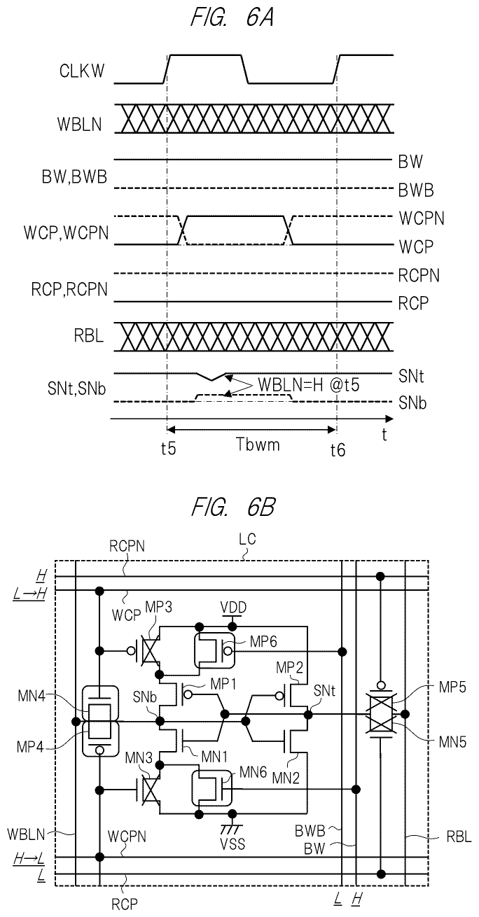

FIG. 6A is a timing chart illustrating an example of the bit write mask operation executed by the latch cell LC illustrated in FIG. 3. FIG. 6B is a schematic view for supplimentarily describing the operation illustrated in FIG. 6A. FIG. 6B illustrates a state of each signal line in the latch cell LC and an on/off state of each transistor in the bit write mask period. In FIG. 6A, a period from a time t5 to a time t6, which is one period of the use-in-writing clock signal CLKW, is a bit write mask period Tbwm.

The bit write mask period Tbwm differs from the writing period Twt illustrated in FIG. 4A in a state of the bit write mask selection line BW. That is, in the bit write mask period Tbwm, the bit write mask selection line BW is in the active state, that is, with the H level in this case. Correspondingly, the pMOS transistor MP6 and the nMOS transistor MN6 are each in the on state. As a result, the inverted-side storage node SNb is driven by the high potential-side power supply voltage VDD or the low potential-side power supply voltage VSS, as different from the case of FIG. 4A.

In this state, it is assumed that, for example, the inverted-side storage node SNb stores the L level. As described in FIGS. 1 and 2, the write bit line WBLN has a high impedance in the bit write mask period Tbwm. That is, a voltage level of the write bit line WBLN is unstable. The pMOS transistor MP4 and the nMOS transistor MN4 in the on state each connect the write bit line WBLN having the unstable voltage level to the inverted-side storage node SNb.

In this case, if the write bit line WBLN is maintained with the H level, a voltage level of the inverted-side storage node SNb may also temporarily slightly rise from the L level. Correspondingly, a voltage level of the non-inverted-side storage node SNt may also temporarily slightly drop from the H level. However, each of the storage nodes SNb and SNt is driven by the high potential-side power supply voltage VDD or the low potential-side power supply voltage VSS. Accordingly, an original voltage level can be maintained as it is. As a result, the inverted-side storage node SNb can be maintained with the L level, regardless of the write operation.

Note that the case where the write operation and the read operation do not overlap each other in the same latch cell LC has been described. On the other hand, in a two-port memory, the write operation and the read operation may overlap each other in the same latch cell LC. In this case, by a specification or setting, it is determined which one of the write operation and the read operation a priority is given to. The latch cell LC desirably handles both the cases.

For example, if the priority is given to the write operation, the read selection line RCP is also activated in FIGS. 4A and 4B. Correspondingly, the pMOS transistor MP5 and the nMOS transistor MN5 are each controlled to be on. In this state, it is necessary to ensure that the correct write data is written into the inverted-side storage node SNb.

On the other hand, if the priority is given to the read operation, the write selection line WCP is also activated in FIGS. 5A and 5B. Correspondingly, the pMOS transistor MP4 and the nMOS transistor MN4 are each controlled to be on. In this case, in response to the activation of the bit write mask selection line BW, the write bit line WBLN is controlled to have a high impedance by the write driver WDV illustrated in FIG. 2. In this state, it is necessary to ensure that the correct read data can be read out from the non-inverted-side storage node SNt.

### MEMORY OF COMPARATIVE EXAMPLE

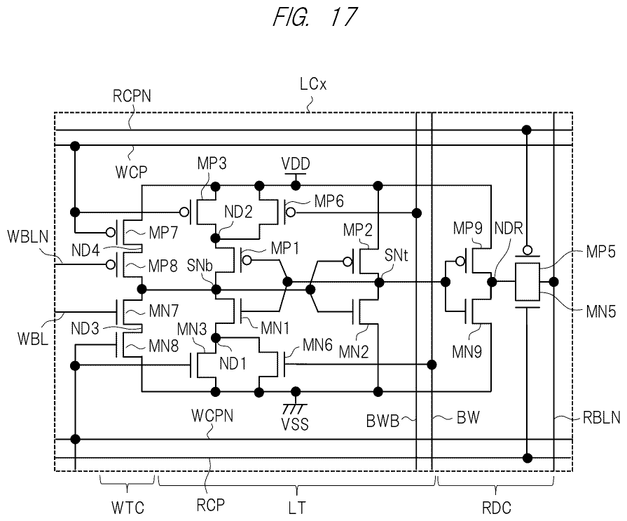

FIG. 17 is a circuit diagram illustrating a configuration example of a latch cell LCx as a comparative example. The latch cell LCx as the comparison example differs from that in the configuration example illustrated in FIG. 3 in respective configurations of a write port circuit WTC and a read port circuit RDC. The write port circuit WTC illustrated in FIG. 17 is made of a driver circuit made of two pMOS transistors MP7 and MP8 and two nMOS transistors MN7 and MN8. The read port circuit RDC is made of a transfer gate and a driver circuit made of a pMOS transistor MP9 and an nMOS transistor MN9. The transfer gate is made of a pMOS transistor MP5 and an nMOS transistor MN5 as similar to the case of FIG. 3.

Thus, the latch cell LCx as the comparison example is made of a total of 16 transistors. On the other hand, the latch cell LC illustrated in FIG. 3 is made of a total of 12 transistors. As a result, the area of the semiconductor device having the small-capacity memory can be reduced. Specifically, the area of the semiconductor device can be reduced by use of the D-latch macro. In addition to this, a reduction in the number of transistors in the latch cell LC can reduce the area of the D-latch macro itself, and can further reduce the area of the semiconductor device. Particularly, even when the D-latch macros are respectively distributed to portions of the semiconductor device, the increase in the area can be suppressed.

If each of the write port circuit WTC and the read port circuit RDC is made of only the transfer gate as illustrated in FIG. 3, the latch cell LC is easily influenced by the port-to-port interference. The port-to-port interference is a phenomenon in which, when the read operation and the write operation simultaneously occur in the same latch cell LC, one of the operations inhibits the other operation as described above. Specifically, the phenomenon is a phenomenon in which the write bit line WBLN and the read bit line RBL interfere with each other through the latch circuit LT.

For example, when the configuration example illustrated in FIG. 17 is used, the write bit line WBLN and the latch circuit LT are separated from each other by a driver circuit in the write port circuit WTC. Similarly, the read bit line RBL and the latch circuit LT are separated from each other by a driver circuit in the read port circuit RDC. Accordingly, the influence of the port-to-port interference can be made small. On the other hand, the influence of the port-to-port interference is made large if each of the write port circuit WTC and the read port circuit RDC is made of only the transfer gate as illustrated in FIG. 3 in order to reduce the area.

When the influence of the port-to-port interference is large, for example, the unstable latch cell that may be defective in the market may be also formed depending on the manufacturing variation in the latch cells LC. Accordingly, in the wafer test, it is desired to, for example, execute a disturb test for reproducing the worst state maximizing the influence of the port-to-port interference. As a result, it is desired to detect the unstable latch cell LC and then remove the semiconductor device including the unstable latch cell LC, or to relieve the unstable latch cell LC by using a relief latch cell LC.

Regarding the worst state described here, the write bit line WBLN and the read bit line RBL respectively hold previous write data and read data by using a parasitic capacitance. The worst state is reproduced based on, for example, a combination of a logic level of the held data, a logic level of the stored data in the latch circuit LT, and the like. Accordingly, it is not easy to reproduce the worst state.

That is, it may be difficult to reproduce the worst state from only a normal external input signal to the D-latch macro as illustrated in FIGS. 1 and 2. Alternatively, in order to reproduce the worst state, it is necessary to input and output a complicated test pattern by using a plurality of cycles. When the worst state cannot be reproduced, the defect yield of the semiconductor devices may increase in a final test after the wafer test or in the market after shipment.

### DISTURB TEST

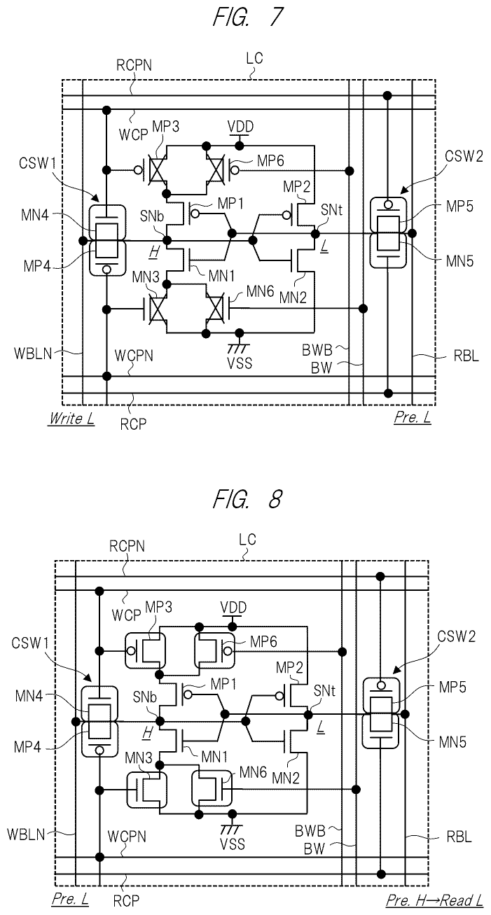

FIG. 7 is a schematic view illustrating an example of the worst state caused by a port-to-port interference in the write operation in the semiconductor device illustrated in FIGS. 1 and 3. FIG. 7 illustrates the on/off state of each transistor in the latch cell LC illustrated in FIG. 3 and the worst state of each signal line maximizing the port-to-port interference. The worst state may be caused when the priority is given to the write operation in the two-port memory as described above.

In FIG. 7, in addition to the on/off state of each transistor illustrated in FIG. 4B, the CMOS switch CSW2 is further controlled to be on. The inverted-side storage node SNb and the non-inverted-side storage node SNt previously store the H level and the L level, respectively. The read bit line RBL is maintained with the L level by a parasitic capacitance in response to the previous read operation. In this state, it is assumed that the inverted-side storage node SNb is rewritten from the H level to the L level through the CMOS switch CSW1.

In this case, the non-inverted-side storage node SNt is connected to the read bit line RBL that is maintained with the L level through the CMOS switch CSW2. Accordingly, the non-inverted-side storage node SNt is easily maintained with the L level. Correspondingly, the inverted-side storage node SNb is easily maintained with the H level. As a result, the unstable latch cell LC in which the inverted-side storage node SNb cannot be rewritten into the L level may be formed. Note that the similar problem may also occur when the inverted-side storage node SNb is rewritten from the L level to the H level by replacing each signal logic level.

A disturb write test is a test for reproducing such a worst state to detect the unstable latch cell LC in which the inverted-side storage node SNb cannot be normally rewritten. That is, the disturb write test is a test for rewriting the inverted-side storage node SNb from a first logic level to a second logic level in opposite phase thereto while the two CMOS switches CSW1 and CSW2 are respectively controlled to be on in the overlapping time periods. Further, as a premise, the disturb write test is a test for precharging the read bit line RBL to a second logic level before the CMOS switch CSW2 is controlled to be on.

FIG. 8 is a schematic view illustrating an example of the worst state caused by the port-to-port interference in the read operation in the semiconductor device illustrated in FIGS. 1 and 3. FIG. 8 illustrates the on/off state of each transistor in the latch cell LC illustrated in FIG. 3 and the worst state of each signal line maximizing the port-to-port interference. The worst state may be caused when the priority is given to the read operation in the two-port memory as described above.

In FIG. 8, in addition to the on/off state of each transistor illustrated in FIG. 5B, the CMOS switch CSW1 is further controlled to be on. The inverted-side storage node SNb and the non-inverted-side storage node SNt previously store the H level and the L level, respectively. The read bit line RBL is maintained with the H level by a parasitic capacitance in response to the previous read operation. Further, the write bit line WBLN is maintained with the L level by a parasitic capacitance in response to the previous write operation. In this state, it is assumed that the L level is read out from the non-inverted-side storage node SNt through the CMOS switch CSW2.

In this case, the inverted-side storage node SNb is connected to the write bit line WBLN that is maintained with the L level through the CMOS switch CSW1. Accordingly, the non-inverted-side storage node SNt easily shifts from the H level to the L level. Correspondingly, the non-inverted-side storage node SNt easily shifts from the L level to the H level.

Further, the non-inverted-side storage node SNt is connected to the read bit line RBL that is maintained with the H level through the CMOS switch CSW2. Accordingly, the non-inverted-side storage node SNt easily shifts from the L level to the H level. As a result, the unstable latch cell LC in which the L level cannot be read out from the non-inverted-side storage node SNt may be formed. Note that the similar problem may also occur when the H level is read out from the non-inverted-side storage node SNt by replacing each signal logic level.

A disturb read test is a test for reproducing such a worst state to detect the unstable latch cell LC in which the normal reading cannot be executed from the non-inverted-side storage node SNt. That is, the disturb read test is a test for controlling the two CMOS switches CSW1 and CSW2 to be on, respectively, in the overlapping time period while the inverted-side storage node SNb stores a first logic level. The disturb read test is a test for reading out a second logic level in opposite phase to the first logic level from the non-inverted-side storage node SNt through the CMOS switch CSW2.

Further, as a premise, the disturb read test is a test for precharging the read bit line RBL to the first logic level before the CMOS switch CSW2 is controlled to be on. In addition to this, the disturb read test is a test for precharging the write bit line WBLN to the second logic level before the CMOS switch CSW1 is controlled to be on.

The disturb write test and the disturb read test may be difficult to achieve the reproduction from only the normal external input signal to the D-latch macro as described above. Accordingly, the data input/output circuit IOC illustrated in FIG. 2 includes two disturb test circuits DTBR and DTBW. The two disturb test circuits DTBR and DTBW each precharge the read bit line RBL[i] or the write bit line WBLN[i] to a predetermined logic level.

### DETAILS OF DATA INPUT/OUTPUT CIRCUIT

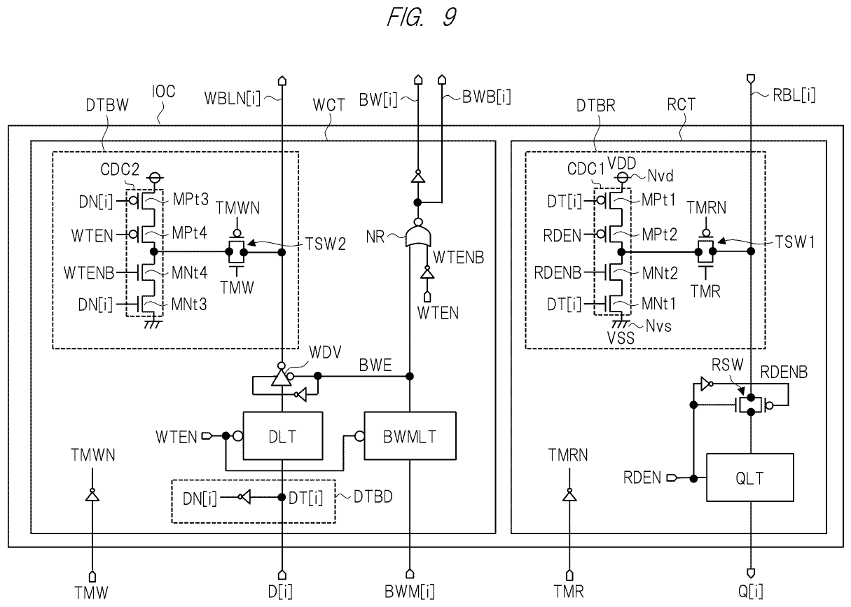

FIG. 9 is a circuit diagram illustrating a more detailed configuration example of the data input/output circuit IOC illustrated in FIG. 2. The data input/output circuit IOC illustrated in FIG. 9 includes a write circuit WCT and a read circuit RCT. The write circuit WCT includes the write latch circuit DLT, the write driver WDV, and the disturb test circuit DTBW illustrated in FIG. 2. In addition to them, the write circuit WCT includes a disturb data setting circuit DTBD, a bit write mask clutch circuit BWMLT, and a NOR gate NR.

On the other hand, the read circuit RCT includes the read latch circuit QLT, the read switch RSW, and the disturb test circuit DTBR as similar to the case of FIG. 2. First, a circuit excluding the disturb data setting circuit DTBD and the two disturb test circuits DTBW and DTBR will be described.

In the write circuit WCT, the write latch circuit WCT latches external input data D[i] as the write data in response to a write enable signal WTEN, as described in FIG. 2. The write driver WDV drives the write bit line WBLN[i], based on the latched write data.

The bit write mask latch circuit BWMLT latches a bit write mask signal BWM[i] from outside in response to a write enable signal WTEN. Then, the bit write mask clutch circuit BWMLT outputs a bit write mask enable signal BWE as a latch result. For example, if the bit write mask signal BWM[i] is with the H level, that is, an assertion level, the bit write mask enable signal BWE is also with the H level.

The write driver WDV is a tri-state circuit controlled by the bit write mask enable signal BWE. The write driver WDV outputs a high impedance to the write bit line WBLN[i] when the bit write mask enable signal BWE is with the H level. On the other hand, the write driver WDV drives the write bit line WBLN[i] to an opposite phase, based on the write data from the write latch circuit DLT when the bit write mask enable signal BWE is with the L level.

The NOR gate NR receives the bit write mask enable signal BWE and an inverted write enable signal WTENB as an inverted signal of the write enable signal WTEN as its input, and executes a NOR operation. Then, the NOR gate NR outputs a signal obtained by the NOR operation to an inverted-side bit write mask selection line BWB[i]. The NOR gate NR outputs the signal obtained by the NOR operation to a non-inverted-side bit write mask selection line BW[i] through an inverter circuit.

For example, if the write enable signal WTEN is with the L level, that is, in the non-write operation, the non-inverted-side bit write mask selection line BW[i] is fixed to the H level. On the other hand, if the write enable signal WTEN is with the H level, a logic level of the non-inverted-side bit write mask selection line BW[i] is controlled based on the bit write mask enable signal BWE. That is, the logic level of the non-inverted-side bit write mask selection signal BW[i] is controlled to the H level/L level when the bit write mask enable signal BWE is with the H level/L level, respectively.

In the read circuit RCT, the read latch circuit QLT receives the data as its input read out from the read bit line RBL[i] through the switch RSW, as described in FIG. 2. The read latch circuit QLT latches the input read data in response to a read enable signal RDEN. Then, the read latch circuit QLT outputs the latched read data as external output data Q[i] to outside.

The read switch RSW is made of, for example, a CMOS switch. The read switch RSW is controlled by the read enable signal RDEN and an inverted read enable signal RDENB as an inverted signal of the read enable signal RDEN. The read switch RSW connects the read bit line RBL[i] to the read latch circuit QLT when the read enable signal RDEN is with the H level, that is, the assertion level.

### DETAILS OF DISTURB TEST CIRCUIT

The disturb test circuit (first test circuit) DTBR is connected to the read bit line RBL[i]. On the other hand, the disturb test circuit (second test circuit) DTBW is connected to the write bit line WBLN[i]. The disturb test circuit DTBR is used both in execution of the disturb write test described in FIG. 7 and execution of the disturb read test described in FIG. 8. On the other hand, the disturb test circuit DTBW is used in execution of the disturb read test.

The disturb test circuit DTBR precharges the read bit line RBL[i] to the second logic level before the CMOS switch CSW2 is controlled to be on in execution of the disturb write test. The second logic level is the L level in the example illustrated in FIG. 7. The disturb test circuit DTBR precharges the read bit line RBL[i] to the first logic level before the CMOS switch CSW2 is controlled to be on in execution of the disturb read test. The first logic level is the H level in the example illustrated in FIG. 8.

The disturb test circuit DTBR uses the external input data D[i] from outside in order to determine the second logic level or the first logic level. Although described in detail later, the same applies to the disturb test circuit DTBW. The disturb data setting circuit DTBD generates positive phase input data DT[i], which is in phase with the external input data D[i], and a reverse phase input data DN[i], which is in opposite phase thereto. In this manner, the external input data D[i] can be flexibly used.

The disturb test circuit DTBR specifically includes a charge/discharge circuit (first charge/discharge circuit) CDC1 and a test mode switch (first test mode switch) TSW1. At a negation period of the read enable signal RDEN, the charge/discharge circuit CDC1 charges or discharges the read bit line RBL[i], based on the positive phase input data DT[i], consequently based on the external input data D[i]. At the negation period of the read enable signal RDEN, the CMOS switch CSW2 is controlled to be off.

The test mode switch TSW1 connects the charge/discharge circuit CDC1 to the read bit line RBL[i] at an assertion period of a test mode signal TMR. The test mode signal TMR is maintained with the assertion level at a period of execution of the disturb write test. Further, the test mode signal TMR is also maintained with the assertion level at a period of execution of the disturb read test. The test mode switch TSW1 is made of, for example, a CMOS switch. In this case, on/off of the test mode switch TSW1 is controlled by the test mode signal TMR and an inverted test mode signal TMRN as an inverted signal of the test mode signal TMR.

The charge/discharge circuit CDC1 more specifically includes two test pMOS transistors MPt1 and MPt2 and two test nMOS transistors MNt1 and MNt2. The two test pMOS transistors MPt1 and MPt2 are connected in series between the high potential-side power supply node Nvd and the read bit line RBL[i] through the test mode switch TSW1. The two test nMOS transistors MNt1 and MNt2 are connected in series between the low potential-side power supply node Nvs and the read bit line RBL[i] through the test mode switch TSW1.

On/off of the test pMOS transistor (first test pMOS transistor) MPt1 and the test nMOS transistor (first test nMOS transistor) MNt1 is complementarily controlled based on the positive phase input data DT[i]. On the other hand, on/off of the test pMOS transistor (second test pMOS transistor) MPt2 is controlled by the read enable signal RDEN. On/off of the test nMOS transistor (second test nMOS transistor) MNt2 is controlled by the inverted read enable signal RDENB.

In this manner, the test pMOS transistor MPt2 and the test nMOS transistor MNt2 are controlled to be on at the negation period of the read enable signal RDEN, consequently at the off period of the CMOS switch CSW2. Correspondingly, the disturb test circuit DTBR precharges the read bit line RBL[i] to the high potential-side power supply voltage VDD or the low potential-side power supply voltage VSS at the off period of the CMOS switch CSW2. On the other hand, the disturb test circuit DTBR outputs a high impedance to the read bit line RBL[i] at the assertion period of the read enable signal RDEN, consequently at the on period of the CMOS switch CSW2.

In execution of the disturb read test, the disturb test circuit DTBW precharges the write bit line WBLN[i] to the second logic level before the CMOS switch CSW1 is controlled to be on. The second logic level is the L level in the example illustrated in FIG. 8. The disturb test circuit DTBW determines the second logic level using the external input data D[i] as similar to the case of the disturb test circuit DTBR.

The disturb test circuit DTBW specifically includes a charge/discharge circuit (second charge/discharge circuit) CDC2 and a test mode switch (second test mode switch) TSW2. At the negation period of the write enable signal WTEN, the charge/discharge circuit CDC2 charges or discharges the write bit line WBLN[i], based on the reverse phase input data DN[i], consequently based on the external input data D[i]. That is, when the external input data D[i] is input into the charge/discharge circuit CDC1, data in opposite phase thereto is input into the charge/discharge circuit CDC2. At the negation period of the write enable signal WTEN, the CMOS switch CSW1 is controlled to be off.

The test mode switch TSW2 connects the charge/discharge circuit CDC2 to the write bit line WBLN[i] at an assertion period of a test mode signal TMW. The test mode signal TMW is maintained with the assertion level at a period of execution of the disturb read test. The test mode switch TSW2 is made of, for example, a CMOS switch. In this case, on/off of the test mode switch TSW2 is controlled by the test mode signal TMW and an inverted test mode signal TMWN as an inverted signal of the test mode signal TMW.

The charge/discharge circuit CDC2 more specifically includes two test pMOS transistors MPt3 and MPt4 and two test nMOS transistors MNt3 and MNt4. The two test pMOS transistors MPt3 and MPt4 are connected in series between the high potential-side power supply node Nvd and the write bit line WBLN[i] through the test mode switch TSW2. The two test nMOS transistors MNt3 and MNt4 are connected in series between the low potential-side power supply node Nvs and the write bit line WBLN[i] through the test mode switch TSW2.

On/off of the test pMOS transistor (third test pMOS transistor) MPt3 and the test nMOS transistor (third test nMOS transistor) MNt3 is complementarily controlled based on the reverse phase input data DN[i]. On the other hand, on/off of the test pMOS transistor (fourth test pMOS transistor) MPt4 is controlled by the write enable signal WTEN. On/off of the test nMOS transistor (fourth test nMOS transistor) MNt4 is controlled by the inverted write enable signal WTENB. The inverted write enable signal WTENB is an inverted signal of the write enable signal WTEN.

In this manner, the test pMOS transistor MPt4 and the test nMOS transistor MNt4 are controlled to be on at the negation period of the write enable signal WTEN, consequently at the off period of the CMOS switch CSW1. Correspondingly, the disturb test circuit DTBW precharges the write bit line WBLN[i] to the high potential-side power supply voltage VDD or the low potential-side power supply voltage VSS at the off period of CMOS switch CSW1. On the other hand, the disturb test circuit DTBW outputs a high impedance to the write bit line WBLN[i] at the assertion period of the write enable signal WTEN, consequently at the on period of the CMOS switch CSW1.

Thus, the two disturb test circuits DTBW and DTBR precharge the write bit line WBLN[i] and the read bit line RBL[i], respectively, at the off periods of the CMOS switches CSW1 and CSW2. Accordingly, particularly a high-speed response is not required for the two disturb test circuits DTBW and DTBR. As a result, each of the MOS transistors can be configured with a relatively small size. Accordingly, an area overhead caused by arrangement of the two disturb test circuits DTBW and DTBR can also be suppressed.

### DETAILS OF DISTURB WRITE TEST

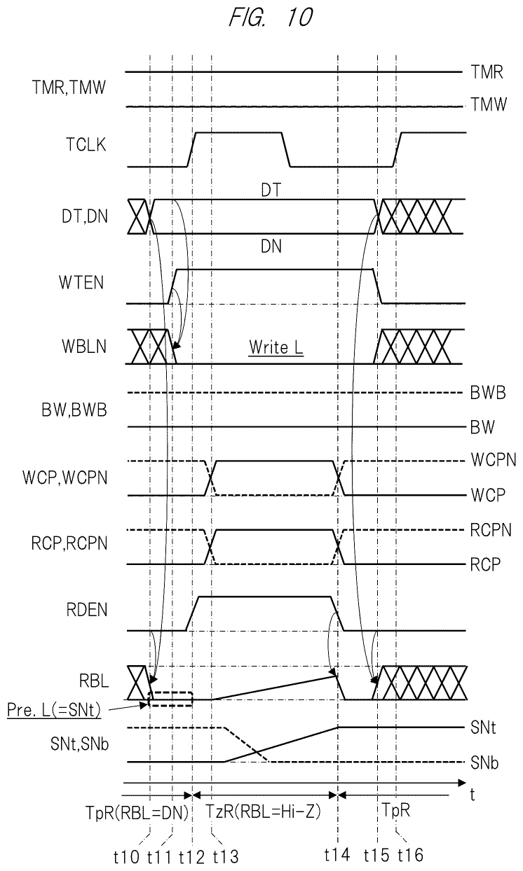

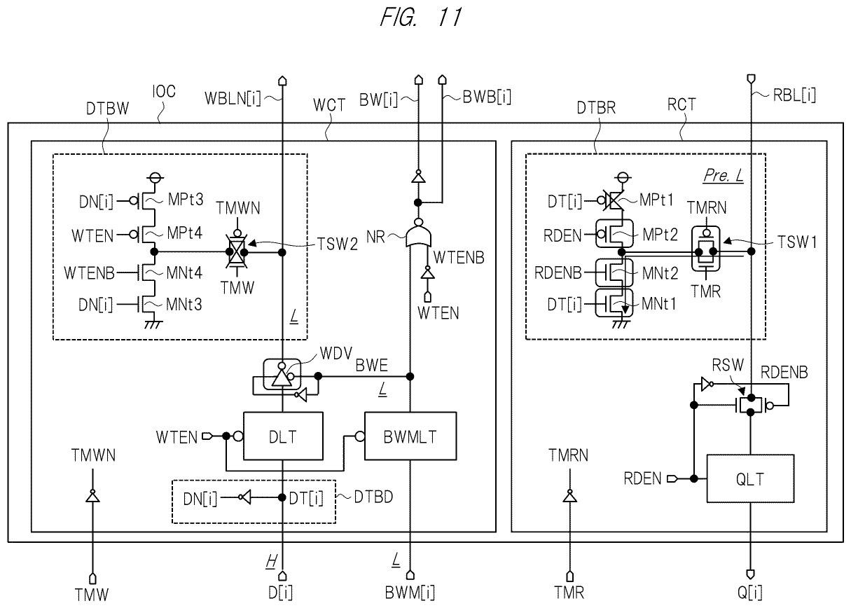

FIG. 10 is a timing chart illustrating an operation example of the disturb write test using the disturb test circuit DTBR illustrated in FIG. 9. FIG. 11 is a schematic view for supplementarily describing the precharge operation executed by the disturb test circuit DTBR in FIG. 10. In FIG. 10, the disturb write test as described in FIG. 7 is executed. FIG. 11 illustrates an on/off state of each transistor in the data input/output circuit IOC illustrated in FIG. 9 and a state of each signal line at a precharge period TpR illustrated in FIG. 10.

In FIG. 10, a test mode signal TMR and a test mode signal TMW are respectively controlled to the assertion level and the negation level. Correspondingly, only one test mode switch TSW1 is controlled to be on. The memory control circuit CTRL illustrated in FIGS. 1 and 2 further receives the use-in-testing clock signal TCLK as its input. The memory control circuit CTRL simultaneously activates a predetermined write word line WWLN[k] and read word line RWLN[k] in response to a rising edge of the use-in-testing clock signal TCLK at a time t12. Correspondingly, the write selection line WCP and the read selection line RCP are simultaneously activated at a period from a time t13 to a time t14.

In this example, the read enable signal RDEN is with the assertion level at a period from the time t12 to the time t14. The disturb test circuit DTBR outputs a high impedance to the read bit line RBL at a high impedance period TzR as the assertion period of the read enable signal RDEN. On the other hand, the disturb test circuit DTBR precharges the read bit line RBL at the precharge period TpR as the negation period of the read enable signal RDEN.

The data input/output circuit IOC receives the external input data D[i] with the H level at a time t10 before the time t12. Correspondingly, at the time t10, the disturb data setting circuit DTBD generates the positive phase input data DT with the H level and the reverse phase input data DN with the L level. At the time t10, the disturb test circuit DTBR precharges the read bit line RBL to the L level, based on the positive phase input data DT with the H level and the read enable signal RDEN with the negation level. The precharge to the L level is maintained until the time t12 of shift to the high impedance period TzR.

In this example, the write enable signal WTEN is with the assertion level at a period from a time t11 to a time t15. The time t11 is a time between the time t10 at which the external input data D[i] is defined and the time t12 at which the use-in-testing clock signal TCLK rises. The time t15 is a time after the time t14 at which the write selection line WCP is deactivated and before a time t16 at which a next rising edge of the use-in-testing clock signal TCLK occurs.

At the time t11, the data input/output circuit IOC latches the external input data D[i] with the H level in response to rising of the write enable signal WTEN. Then, the data input/output circuit IOC drives the write bit line WBLN to the L level through the write driver WDV.

As described in FIG. 7, the inverted-side storage node SNb previously stores the H level. At the time t13, the inverted-side storage node SNb is connected to the write bit line WBLN that is driven to the L level. In the stable latch cell LC, the inverted-side storage node SNb shifts from the H level to the L level. On the other hand, in the unstable latch cell LC, the inverted-side storage node SNb cannot sufficiently shift to the L level due to an interference from the read bit line RBL that has been precharged to the L level.

FIG. 11 illustrates a state of the data input/output circuit IOC at a period from the time t10 to the time t12 in FIG. 10. The external input data D[i] and the positive phase input data DT[i] are each with the H level. The write bit line WBLN[i] is with the L level. The disturb test circuit DTBR receives the read enable signal RDEN with the L level and the positive phase input data DT[i] with the H level as its input. In this manner, the disturb test circuit DTBR precharges the read bit line RBL[i] to the L level through the two test nMOS transistors MNt2 and MNt1 that are turned on.

### DETAILS OF DISTURB READ TEST

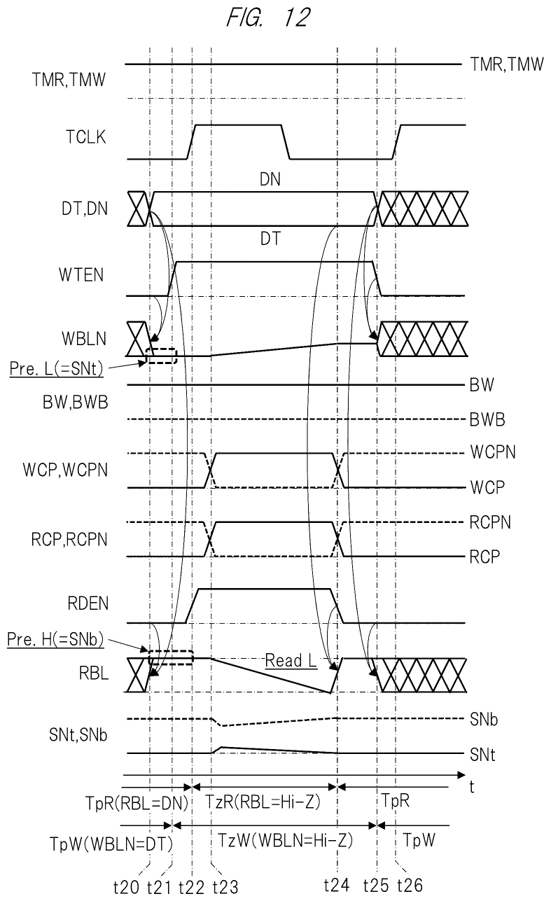

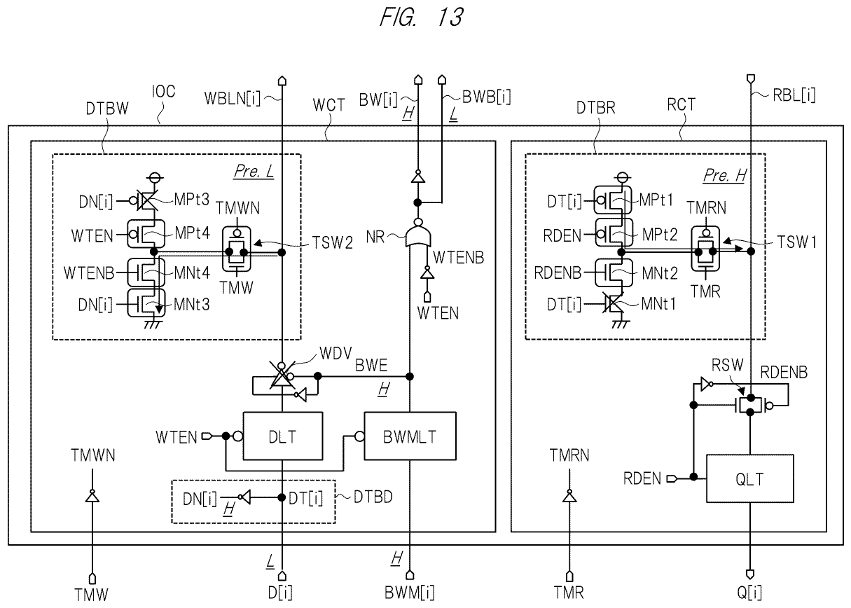

FIG. 12 is a timing chart illustrating an operation example of the disturb read test using the two disturb test circuits DTBR and DTBW illustrated in FIG. 9. FIG. 13 is a schematic view for supplementarily describing the precharge operation executed by the two disturb test circuits DTBR and DTBW in FIG. 12. In FIG. 12, the disturb read test as described in FIG. 8 is executed. FIG. 13 illustrates an on/off state of each transistor in the data input/output circuit IOC illustrated in FIG. 9 and a state of each signal line at the precharge periods TpR and TpW illustrated in FIG. 12.

Times t20 to t26 illustrated in FIG. 12 are respectively similar to the times t10 to t16 illustrated in FIG. 10. FIG. 12 differs from FIG. 10 in the following three points. A first difference is that two test mode signals TMR and TMW are both controlled to the assertion level. Correspondingly, the two test mode switches TSW1 and TSW2 are both controlled to be on. A second difference is that external input data D[i] with the L level is input at the time t20, as opposed to the case of FIG. 11. Correspondingly, the disturb data setting circuit DTBD generates positive phase input data DT with the L level and reverse phase input data DN with the H level.

A third difference is that the bit write mask selection line BW is controlled to be activated. Correspondingly, the write driver WDV illustrated in FIG. 9 outputs a high impedance to the write bit line WBLN. As a result, a voltage level of the write bit line WBLN is controlled by the disturb test circuit DTBW.

The disturb test circuit DTBW outputs a high impedance to the write bit line WBLN at a period from the time t21 to the time t25 as the assertion period of the write enable signal WTEN. That is, the period from the time t21 to the time t25 is a high impedance period TzW of the write bit line WBLN. On the other hand, the disturb test circuit DTBW precharges the write bit line WBLN at a period excluding the period from the time t21 to the time t25 as the negation period of the write enable signal WTEN. That is, the period excluding the period from the time t21 to the time t25 is a precharge period TpW of the write bit line WBLN.

Specifically, at the time t20, the disturb test circuit DTBW precharges the write bit line WBLN to the L level, based on the reverse phase input data DN with the H level and the write enable signal WTEN with the negation level. The precharge to the L level is maintained until the time t21 at which the write bit line WBLN shifts to the high impedance period TzW.

On the other hand, at the time t20, the disturb test circuit DTBR precharges the read bit line RBL to the H level, based on the positive phase input data DT with the L level and the read enable signal RDEN with the negation level. The precharge to the H level is maintained until the time t22 at which the read bit line RBL shifts to the high impedance period TzR.

As described in FIG. 8, the non-inverted-side storage node SNt previously stores the L level. At the time t23, the non-inverted-side storage node SNt is connected to the read bit line RBL that is maintained with the H level. In the stable latch cell LC, the read bit line RBL shifts from the H level to the L level. On the other hand, in the unstable latch cell LC, the read bit line RBL cannot sufficiently shift to the L level due to an interference from the write bit line WBLN that has been precharged to the L level.

For example, at the L level period of the read enable signal RDEN, the read latch circuit QLT illustrated in FIG. 9 latches the read data at a time of drop of the read enable signal RDEN. If the shift of the read bit line RBL to the L level is insufficient at the time t24 that is the time of the drop of the read enable signal RDEN, the read latch circuit QLT may erroneously latch the H level.

FIG. 13 illustrates a state of the data input/output circuit IOC at a period from the time t20 to the time t21 in FIG. 12. The external input data D[i] and the positive phase input data DT[i] are with the L level. The reverse phase data DN[i] is with the H level. The write driver WDV outputs a high impedance to the write bit line WBLN[i] in response to the H level of the bit write mask enable signal BWE.

In this state, the disturb test circuit DTBW receives the write enable signal WTEN with the L level and the reverse phase input data DN[i] with the H level as its input. In this manner, the disturb test circuit DTBW precharges the write bit line WBLN[i] to the L level through the two test nMOS transistors MNt4 and MNt3 that are turned on. On the other hand, the disturb test circuit DTBR receives the read enable signal RDEN with the L level and the positive phase input data DT[i] with the L level as its input. In this manner, the disturb test circuit DTBR precharges the read bit line RBL[i] to the H level through the two test pMOS transistors MPt1 and MPt2 that are turned on.

### METHOD OF MANUFACTURING SEMICONDUCTOR DEVICE

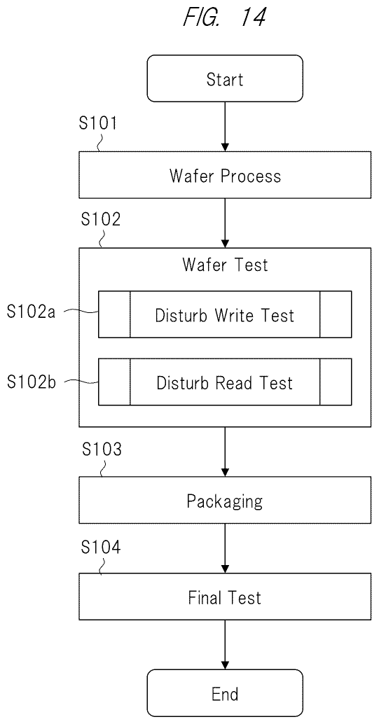

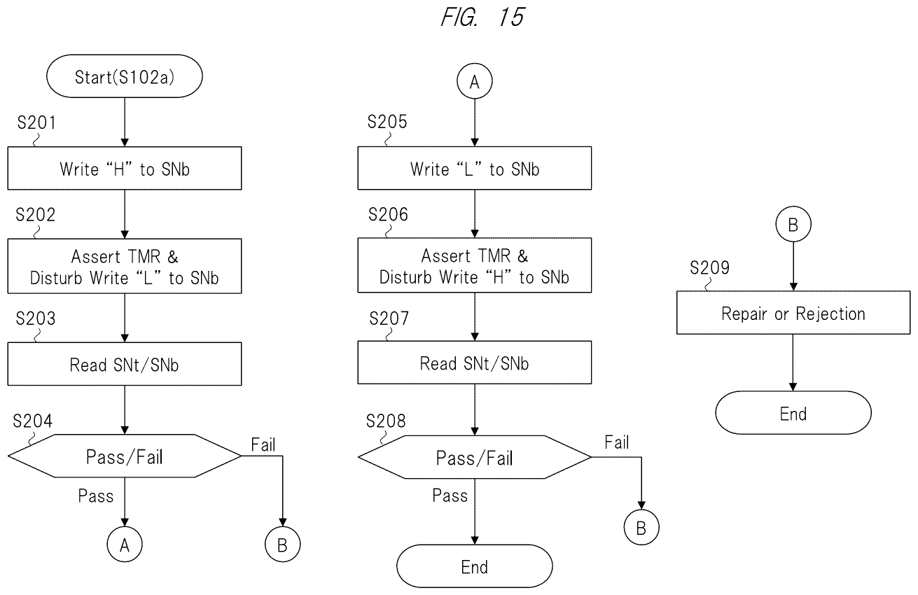

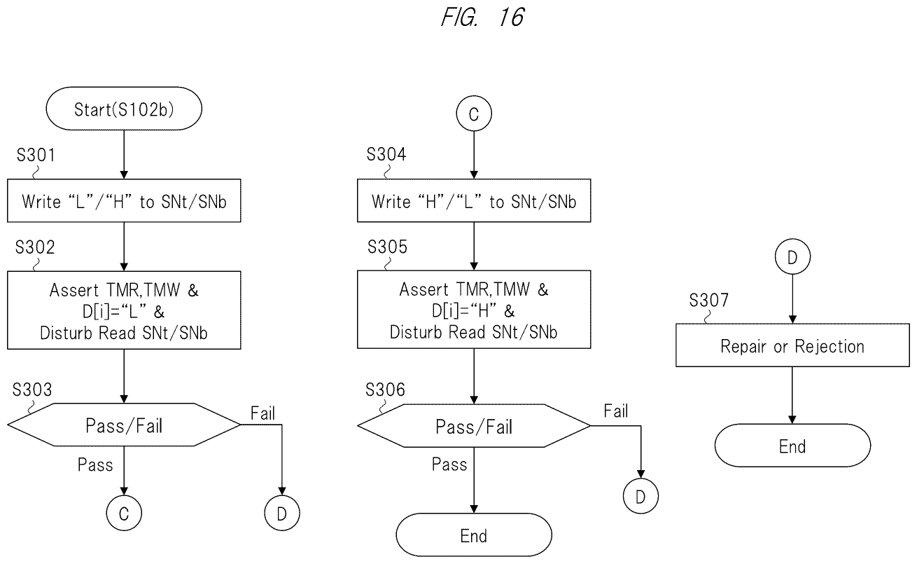

FIG. 14 is a flowchart illustrating an example of a method of manufacturing the semiconductor device according to one embodiment. FIG. 15 is a flowchart illustrating an example of a disturb write test (step S102a) illustrated in FIG. 14. FIG. 16 is a flowchart illustrating an example of a disturb read test (step S102b) illustrated in FIG. 14. The manufacturing method illustrated in FIG. 14 includes a wafer process step (step S101), a wafer test step (step S102), a packaging step (step S103), and a final test step (step S104).

In the wafer process step (step S101), various types of semiconductor manufacturing apparatuses each form a plurality of semiconductor devices on a semiconductor wafer. In each of the plurality of semiconductor devices, a memory MEM including two disturb test circuits DTBR and DTBW as illustrated in FIGS. 1, 3, and 9 is formed.

In the wafer test step (step S102), for example, a probe inspection apparatus electrically tests each of the plurality of semiconductor devices, consequently the memory MEM, formed on the semiconductor wafer. The wafer test step includes the disturb write test (step S102a) and the disturb read test (step S102b) as respectively illustrated in FIGS. 15 and 16.

In the packaging step (step S103), various types of assembly apparatuses each assemble the semiconductor device, that has been determined to be a non-defective product in the wafer test step, into a package. In the final test step (step S104), for example, a semiconductor tester electrically tests the semiconductor device assembled into the package. Then, the semiconductor device has been determined to be a non-defective product in the final test step is shipped to the market.

The manufacturing variation in the wafer process step may form the stable latch cell LC and the unstable latch cell LC against the above-described port-to-port interference. The unstable latch cell LC is desirably detected in the wafer test step. In this manner, the defect yield of the semiconductor devices in the final test step and in the market can be reduced. If the memory MEM illustrated in FIG. 1 includes the relief latch cell LC, the latch cell LC that has been determined to be a defective product can be replaced with the relief latch cell LC. In this manner, a yield in the wafer test step can be improved. Further, since the unstable latch cell LC can be detected in an early stage, a subsequent unnecessary cost such as an assembly cost for the defective product can be reduced.

As described above, it may be difficult to reproduce the worst state as illustrated in FIGS. 7 and 8 from only the supply of the normal external signal to the memory MEM by the probe inspection apparatus. Accordingly, for example, tests as respectively illustrated in FIGS. 15 and 16 are each executed by using the two disturb test circuits DTBR and DTBW. In this manner, the unstable latch cell LC can be detected in the wafer test step, thereby obtaining various types of effects as described above.

First, the disturb write test (step S102a) as illustrated in FIG. 15 will be described. In step S201, the probe inspection apparatus writes the H level into the inverted-side storage node SNb in a target latch cell LC. That is, the probe inspection apparatus executes normal writing into the target latch cell LC by using the use-in-writing clock signal CLKW and the external input data D[i] with the L level.

Then, in step S202, the probe inspection apparatus asserts a test mode signal TMR. Then, the probe inspection apparatus executes disturb writing of the L level into the inverted-side storage node SNb in the target latch cell LC. That is, the probe inspection apparatus executes disturb writing into the target latch cell LC by using the use-in-testing clock signal TCLK and the external input data D[i] with the H level.

Then, in step S203, the probe inspection apparatus executes normal reading from the target latch cell LC by using the use-in-reading clock signal CLKR. In step S204, the probe inspection apparatus determines whether or not the H level has been read out from the target latch cell LC. That is, the probe inspection apparatus determines whether the disturb writing result of the L level into the inverted-side storage node SNb in step S202 indicates the “pass” or “fail”.

If a determination result in step S204 indicates “fail”, the target latch cell LC is replaced with the relief latch cell LC through a predetermined relief procedure in step S209. If the target latch cell LC cannot be relieved, a semiconductor device including the target latch cell LC is removed as the defective product. On the other hand, if the determination result in step S204 indicates “pass”, the process of the probe inspection apparatus shifts to step S205.

In step S205, the probe inspection apparatus writes the L level into the inverted-side storage node SNb in the target latch cell LC, as opposed to that in step S201. Note that the process in step S205 may be omitted in some cases because of the process in step S202. Then, in steps S206 to S208, similar processes to those in steps S202 to 204 described above are executed by using the reverse phase data. If the determination result in step S208 indicates “fail”, the process in step S209 is executed.

Then, the disturb read test (step S102b) as illustrated in FIG. 16 will be described. In step S301, the probe inspection apparatus writes the L level into the non-inverted-side storage node SNt and writes the H level into the inverted-side storage node SNb in a target latch cell LC. That is, the probe inspection apparatus executes normal writing into the target latch cell LC by using the use-in-writing clock signal CLKW and the external input data D[i] with the L level.

Then, in step S302, the probe inspection apparatus asserts both two test mode signals TMR and TMW. Then, the probe inspection apparatus executes disturb reading from the target latch cell LC. That is, the probe inspection apparatus executes disturb reading from the target latch cell LC by using the use-in-testing clock signal TCLK and the external input data D[i] with the L level.

In step S303, the probe inspection apparatus determines whether or not the L level has been read out from the target latch cell LC. That is, the probe inspection apparatus determines whether the disturb reading result of the L level from the non-inverted-side storage node SNt in step S302 indicates the “pass” or “fail”.

If a determination result in step S303 indicates the “fail”, the target latch cell LC is replaced with the relief latch cell LC through a predetermined relief procedure in step S307. If the target latch cell LC cannot be relieved, a semiconductor device including the target latch cell LC is removed as the defective product. On the other hand, if the determination result in step S303 indicates the “pass”, the process of the probe inspection apparatus shifts to step S304.

In step S304, the probe inspection apparatus writes the H level into the non-inverted-side storage node SNt and writes the L level into the inverted-side storage node SNb in the target latch cell LC, as opposed to that in step S301. Then, in steps S305 and S306, similar processes to those in steps S302 and S303 described above are executed by using the reverse phase data. If a determination result in step S306 indicates the “fail”, a process in step S307 is executed.

In this example, note that the probe inspection apparatus executes the write operation, the read operation, and the determination operation by supplying various types of external signals to the memory MEM. Instead of this, for example, a BIST (Built In Self Test) circuit may execute the write operation, the read operation, and the determination operation by supplying various types of external signals to the memory MEM. That is, the semiconductor device according to one embodiment may include the BIST circuit that executes tests as illustrated in FIGS. 15 and 16. In this manner, for example, the number of simultaneous measurements in the wafer test step is not limited by a resource of the probe inspection apparatus, and therefore, a test time period can be shortened.

### MAIN EFFECT OF ONE EMBODIMENT

As described above, in the system according to one embodiment, each latch cell LC configuring the D-latch macro is made of 12 MOS transistors. In order to test the influence of the port-to-port interference due to this, the D-latch macro includes the disturb circuits DTBR and DTBW for reproducing the worst state of the port-to-port interference. In this manner, the unstable latch cell LC as the defective product in the worst state can be detected in the wafer test step, and therefore, the defect yield of the semiconductor devices in the market can be reduced.

In the foregoing, the invention made by the inventors of the present application has been concretely described based on the embodiments. However, the present invention is not limited to the foregoing embodiments, and various modifications can be made within the scope of the present invention. For example, the above-described embodiments have been explained in detail for making the present invention understandable, and are not always limited to the one including all structures explained above. Also, a part of the structure of one embodiment can be replaced with the structure of another embodiment, and besides, the structure of another embodiment can be added to the structure of one embodiment. Further, another structure can be added to/eliminated from/replaced with a part of the structure of each embodiment.

What is claimed is:

1. A semiconductor device comprising:
a pair of write selection lines being activated in a write operation, and being complementary signal lines;
a pair of read selection lines being activated in a read operation, and being complementary signal lines;
a plurality of latch cells being connected to the pair of write selection lines and the pair of read selection lines;
a plurality of read bit lines transferring read data from the plurality of latch cells;
a plurality of write bit lines transferring write data to the plurality of latch cells;
a plurality of pairs of bit write mask selection lines being activated in execution of a write operation of a high impedance to any one of the plurality of latch cells, and being complementary signal lines; and
a plurality of first test circuits being connected to the plurality of read bit lines,
wherein each of the plurality of latch cells includes:
a first storage node and a second storage node storing complementary data;
a first nMOS transistor being connected between the first storage node and a first intermediate node, and having a gate connected to the second storage node;
a second nMOS transistor being connected between the second storage node and a low potential-side power supply node to which a low potential-side power supply voltage is suppled, and having a gate connected to the first storage node;
a third nMOS transistor being connected between the first intermediate node and the low potential-side power supply node, and being controlled by the pair of write selection lines;
a first pMOS transistor being connected between the first storage node and a second intermediate node, and having a gate connected to the second storage node;
a second pMOS transistor being connected between the second storage node and a high potential-side power supply node to which a high potential-side power supply voltage is suppled, and having a gate connected to the first storage node;
a third pMOS transistor being connected between the second intermediate node and the high potential-side power supply node, and being controlled by the pair of write selection lines;
a fourth nMOS transistor and a fourth pMOS transistor configuring a first CMOS switch controlled by the pair of write selection lines, and connecting a predetermined write bit line among the plurality of write bit lines to the first storage node when being controlled to be on;
a fifth nMOS transistor and a fifth pMOS transistor configuring a second CMOS switch controlled by the pair of read selection lines, and connecting the second storage node to a predetermined read bit line among the plurality of read bit lines when being controlled to be on;
a sixth nMOS transistor being connected between the first intermediate node and the low potential-side power supply node, and being controlled by a pair of bit write mask selection lines as any one of the plurality of pairs of bit write mask selection lines; and
a sixth pMOS transistor being connected between the second intermediate node and the high potential-side power supply node, and being controlled by the pair of bit write mask selection lines, and,
when a test for rewriting the first storage node from a first logic level to a second logic level in opposite phase to the first logic level in a state in which the first CMOS switch and the second CMOS switch are respectively controlled to be on in overlapping time periods is a disturb write test,
the plurality of first test circuits precharge the plurality of read bit lines to the second logic level before the second CMOS switch is controlled to be on in execution of the disturb write test.

2. The semiconductor device according to claim 1,
wherein a plurality of external input data for determining a plurality of the write data is input from outside, and
each of the plurality of first test circuits includes:
a first charge/discharge circuit charging or discharging the predetermined read bit line in an off period of the second CMOS switch, based on predetermined external input data among the plurality of external input data; and
a first test mode switch connecting the first charge/discharge circuit to the predetermined read bit line in execution of the disturb write test.

3. The semiconductor device according to claim 2,
wherein the first charge/discharge circuit includes:
a first test pMOS transistor and a second test pMOS transistor being connected in series between the high potential-side power supply node and the predetermined read bit line through the first test mode switch; and
a first test nMOS transistor and a second test nMOS transistor being connected in series between the low potential-side power supply node and the predetermined read bit line through the first test mode switch,
the first test pMOS transistor and the first test nMOS transistor are complementarily controlled to be on/off, based on the predetermined external input data, and
the second test pMOS transistor and the second test nMOS transistor are controlled to be on in an off period of the second CMOS switch.

4. The semiconductor device according to claim 1, further comprising
a plurality of second test circuits being connected to the plurality of write bit lines,
wherein, when a test for controlling the first CMOS switch and the second CMOS switch to be on, respectively, in overlapping time periods in a state in which the first storage node stores the first logic level and then reading out the second logic level from the second storage node through the second CMOS switch is a disturb read test,
the plurality of first test circuits precharge the plurality of read bit lines to the first logic level before the second CMOS switch is controlled to be on in execution of the disturb read test, and
the plurality of second test circuits precharge the plurality of write bit lines to the second logic level before the first CMOS switch is controlled to be on in execution of the disturb read test.

5. The semiconductor device according to claim 4, further comprising:
a plurality of write latch circuits latching a plurality of external input data from outside as a plurality of the write data; and
a plurality of write drivers being connected between the plurality of write latch circuits and the plurality of write bit lines, each being made of a tri-state circuit corresponding to the write operation of the high impedance, and outputting the high impedance in the disturb read test,
wherein each of the plurality of first test circuits includes:
a first charge/discharge circuit charging or discharging the predetermined read bit line in an off period of the second CMOS switch, based on predetermined external input data among the plurality of external input data; and
a first test mode switch connecting the first charge/discharge circuit to the predetermined read bit line in execution of the disturb read test, and
each of the plurality of second test circuits includes:
a second charge/discharge circuit charging or discharging the predetermined write bit line in an off period of the first CMOS switch, based on the predetermined external input data; and
a second test mode switch connecting the second charge/discharge circuit to the predetermined write bit line in execution of the disturb read test.

6. The semiconductor device according to claim 5,
wherein the first charge/discharge circuit includes:
a first test pMOS transistor and a second test pMOS transistor being connected in series between the high potential-side power supply node and the predetermined read bit line through the first test mode switch; and
a first test nMOS transistor and a second test nMOS transistor being connected in series between the low potential-side power supply node and the predetermined read bit line through the first test mode switch,
the first test pMOS transistor and the first test nMOS transistor are complementarily controlled to be on/off, based on the predetermined external input data, and
the second test pMOS transistor and the second test nMOS transistor are controlled to be on in an off period of the second CMOS switch,
the second charge/discharge circuit includes:
a third test pMOS transistor and a fourth test pMOS transistor being connected in series between the high potential-side power supply node and the predetermined write bit line through the second test mode switch; and
a third test nMOS transistor and a fourth test nMOS transistor being connected in series between the low potential-side power supply node and the predetermined write bit line through the second test mode switch,
the third test pMOS transistor and the third test nMOS transistor are complementarily controlled to be on/off, based on the predetermined external input data, and
the fourth test pMOS transistor and the fourth test nMOS transistor are controlled to be on in an off period of the first CMOS switch.

7. The semiconductor device according to claim 5,
wherein, in input of the predetermined external input data into the first charge/discharge circuit, data in opposite phase to the predetermined external input data is input into the second charge/discharge circuit.

8. The semiconductor device according to claim 1, further comprising
a read latch circuit receiving, as its input, and latching the read data transferred to the plurality of read bit lines, without passing through a sense amplifier.

9. A semiconductor device comprising:
a pair of write selection lines being activated in a write operation, and being complementary signal lines;
a pair of read selection lines being activated in a read operation, and being complementary signal lines;
a plurality of latch cells being connected to the pair of write selection lines and the pair of read selection lines;
a plurality of read bit lines transferring read data from the plurality of latch cells;
a plurality of write bit lines transferring write data to the plurality of latch cells;
a plurality of pairs of bit write mask selection lines being activated in execution of a write operation of a high impedance to any one of the plurality of latch cells, and being complementary signal lines;
a plurality of first test circuits being connected to the plurality of read bit lines; and
a plurality of second test circuits being connected to the plurality of write bit lines,
wherein each of the plurality of latch cells includes:
a first storage node and a second storage node storing complementary data;
a first nMOS transistor being connected between the first storage node and a first intermediate node, and having a gate connected to the second storage node;
a second nMOS transistor being connected between the second storage node and a low potential-side power supply node to which a low potential-side power supply voltage is suppled, and having a gate connected to the first storage node;
a third nMOS transistor being connected between the first intermediate node and the low potential-side power supply node, and being controlled by the pair of write selection lines;
a first pMOS transistor being connected between the first storage node and a second intermediate node, and having a gate connected to the second storage node;
a second pMOS transistor being connected between the second storage node and a high potential-side power supply node to which a high potential-side power supply voltage is suppled, and having a gate connected to the first storage node;
a third pMOS transistor being connected between the second intermediate node and the high potential-side power supply node, and being controlled by the pair of write selection lines;
a fourth nMOS transistor and a fourth pMOS transistor configuring a first CMOS switch controlled by the pair of write selection lines, and connecting a predetermined write bit line among the plurality of write bit lines to the first storage node when being controlled to be on;
a fifth nMOS transistor and a fifth pMOS transistor configuring a second CMOS switch controlled by the pair of read selection lines, and connecting the second storage node to a predetermined read bit line among the plurality of read bit lines when being controlled to be on;
a sixth nMOS transistor being connected between the first intermediate node and the low potential-side power supply node, and being controlled by a pair of bit write mask selection lines as any one of the plurality of pairs of bit write mask selection lines; and
a sixth pMOS transistor being connected between the second intermediate node and the high potential-side power supply node, and being controlled by the pair of bit write mask selection lines, and,
when a test for controlling the first CMOS switch and the second CMOS switch to be on in overlapping time periods in a state in which the first storage node stores a first logic level and then reading out a second logic level in opposite phase to the first logic level from the second storage node through the second CMOS switch is a disturb read test,
the plurality of first test circuits precharge the plurality of read bit lines to the first logic level before the second CMOS switch is controlled to be on in execution of the disturb read test, and
the plurality of second test circuits precharge the plurality of write bit lines to the second logic level before the first CMOS switch is controlled to be on in execution of the disturb read test.

10. The semiconductor device according to claim 9, further comprising:
a plurality of write latch circuits latching a plurality of external input data from outside as a plurality of the write data; and
a plurality of write drivers being connected between the plurality of write latch circuits and the plurality of write bit lines, each being made of a tri-state circuit corresponding to the write operation of the high impedance, and outputting the high impedance even in the disturb read test,
wherein each of the plurality of first test circuits includes:
a first charge/discharge circuit charging or discharging the predetermined read bit line in an off period of the second CMOS switch, based on predetermined external input data among the plurality of external input data; and
a first test mode switch connecting the first charge/discharge circuit to the predetermined read bit line in execution of the disturb read test, and
each of the plurality of second test circuits includes:
a second charge/discharge circuit charging or discharging the predetermined write bit line in an off period of the first CMOS switch, based on the predetermined external input data; and
a second test mode switch connecting the second charge/discharge circuit to the predetermined write bit line in execution of the disturb read test.

11. The semiconductor device according to claim 10,
wherein the first charge/discharge circuit includes:
a first test pMOS transistor and a second test pMOS transistor being connected in series between the high potential-side power supply node and the predetermined read bit line through the first test mode switch; and
a first test nMOS transistor and a second test nMOS transistor being connected in series between the low potential-side power supply node and the predetermined read bit line through the first test mode switch,
the first test pMOS transistor and the first test nMOS transistor are complementarily controlled to be on/off, based on the predetermined external input data, and
the second test pMOS transistor and the second test nMOS transistor are controlled to be on in an off period of the second CMOS switch,
the second charge/discharge circuit includes:
a third test pMOS transistor and a fourth test pMOS transistor being connected in series between the high potential-side power supply node and the predetermined write bit line through the second test mode switch; and
a third test nMOS transistor and a fourth test nMOS transistor being connected in series between the low potential-side power supply node and the predetermined write bit line through the second test mode switch,
the third test pMOS transistor and the third test nMOS transistor are complementarily controlled to be on/off, based on the predetermined external input data, and
the fourth test pMOS transistor and the fourth test nMOS transistor are controlled to be on in an off period of the first CMOS switch.

12. The semiconductor device according to claim 10,
wherein, in input of the predetermined external input data into the first charge/discharge circuit, data in opposite phase to the predetermined external input data is input into the second charge/discharge circuit.

13. The semiconductor device according to claim 9, further comprising
a read latch circuit receiving, as its input, and latching the read data transferred to the plurality of read bit lines, without passing through a sense amplifier.
